(19) United States
(12) Patent Application Publication
(10) Pub. No.: US 2018/0219107 A1
(43) Pub. Date: Aug. 2, 2018

(54) BACK SURFACE JUNCTION TYPE SOLAR CELL AND METHOD OF MANUFACTURING SOLAR CELL

(71) Applicant: Panasonic Intellectual Property Management Co., Ltd., Osaka (JP)

(72) Inventor: Keiichiro MASUKO, Osaka (JP)

(21) Appl. No.: 15/936,036

(22) Filed: Mar. 26, 2018

Related U.S. Application Data
(63) Continuation of application No. PCT/JP2016/003699, filed on Aug. 10, 2016.

(30) Foreign Application Priority Data
Sep. 30, 2015 (JP) 2015-193284

(51) Int. Cl. H01L 31/02; H01L 31/0224; H01L 31/18; C25D 7/12

(52) U.S. Cl. CPC H01L 31/0201; H01L 31/022433; H01L 31/0747; C25D 7/126; H01L 31/18

(57) ABSTRACT

A semiconductor substrate has a first area and a second area. A seed layer is provided on a principal surface of the semiconductor substrate including the first area and the second area. Insulating layers are discretely provided on the seed layer in the first area and not provided on the seed layer in the second area. Plating layers in the first area are connected to the seed layer between the discretely provided insulating layers and connected to the seed layer in the second area.

### CROSS-REFERENCE TO RELATED APPLICATION

This application is based upon and claims the benefit of priority from the prior Japanese Patent Application No. 2015-193284, filed on Sep. 30, 2015, the entire contents of which are incorporated herein by reference.

### BACKGROUND

### 1. Field

The disclosure relates to a solar cell and, more particularly, to a back surface junction type solar cell and a method of manufacturing a solar cell.

### 2. Description

Solar cells having high power generation efficiency include back surface junction type solar cells with an n-type semiconductor layer and a p-type semiconductor layer formed on a back surface, which is opposite to a light receiving surface on which light is incident. In back surface junction type solar cells, both an n-side electrode and a p-side electrode to retrieve generated power are provided on the back surface. The n-side electrode and the p-side electrode include a plating layer formed by plating (see, for example, patent document 1).

[patent document 1] JP2012-138545

In a solar cell in which a plating layer is used as an electrode, internal stress in the plating layer may create warp of the solar cell. Where the electrode is formed by plating, the current density is likely to be higher at the outer circumference of the solar cell than at the center, with the result that the plating layer at the outer circumference of the solar cell is likely to be thicker than the plating layer at the center. For this reason, the stress applied at the outer circumference is likely to be higher than the stress applied at the center so that warp is more likely to occur at the outer circumference of the solar cell than at the center of the solar cell.

### SUMMARY

In this background, a general purpose of the present invention is to provide a technology for reducing warp of a solar cell.

A solar cell according to an embodiment of the present invention comprises: a semiconductor substrate having a first area and a second area; a seed layer provided on a principal surface of the semiconductor substrate including the first area and the second area; insulating layers discretely provided on the seed layer in the first area and not provided on the seed layer in the second area; and plating layers in the first area connected to the seed layer between the discretely provided insulating layers and connected to the seed layer in the second area.

Another embodiment of the present invention also relates to a solar cell. The solar cell comprises: a semiconductor substrate; a plurality of finger electrodes extending in a first direction on a principal surface of the semiconductor substrate; and a bus bar electrode connected to one of ends of the plurality of finger electrodes and extending in a second direction perpendicular to the first direction. The bus bar electrode is provided with a plurality of cavities extending in the first direction.

Another embodiment of the present invention relates to a method of manufacturing a solar cell. The method comprises: building a seed layer on a principal surface of a semiconductor substrate having a first area and a second area and building an insulating layer on the seed layer in the first area; removing the insulating layer in the first area discretely; and forming a plating layer in a portion where the seed layer is exposed as a result of removing the insulating layer in the first area discretely, and forming a plating layer on the seed layer in the second area.

### BRIEF DESCRIPTION OF THE DRAWINGS

The figures depict one or more implementations in accordance with the present teaching, by way of example only, not by way of limitations. In the figures, like reference numerals refer to the same or similar elements.

Embodiments will now be described by way of examples only, with reference to the accompanying drawings which are meant to be exemplary, not limiting and wherein like elements are numbered alike in several Figures in which:

FIG. 1 is a cross sectional view illustrating a structure of a solar cell module according to embodiment 1;

FIG. 2 is a plan view illustrating a structure of the solar cell of FIG. 1;

FIG. 3 is a cross sectional view illustrating a structure of the solar cell of FIG. 2;

FIGS. 4A-4C are cross sectional views illustrating steps of manufacturing the solar cell of FIG. 2;

FIG. 5 is a cross sectional view illustrating a structure of the solar cell according to embodiment 2;

FIGS. 6A-6D are cross sectional views illustrating steps of manufacturing the solar cell of FIG. 5;

FIG. 7 is a cross sectional view illustrating a structure of the solar cell according to embodiment 3; and

FIGS. 8A-8E are cross sectional views illustrating steps of manufacturing the solar cell of FIG. 7.

### DETAILED DESCRIPTION

The invention will now be described by reference to the preferred embodiments. This does not intend to limit the scope of the present invention, but to exemplify the invention.

### Embodiment 1

A brief summary will be given before describing the invention in specific details. Embodiment 1 relates to a back surface junction type solar cell in which a pair of comb-shaped electrodes inserted into each other are provided on the back surface opposite to a light receiving surface on which light is incident. As mentioned above, an electric current for producing these electrodes by plating is more concentrated at the outer circumference than at the center with the result that the plating layer at the outer circumference is thicker than the plating layer at the center. Such a difference in the thickness of the plating layer within the plane of a solar cell induces in-plane distribution of stress, creating warp of the solar cell. This is addressed by this embodiment by forming the bus bar electrodes at the outer circumference by providing discrete plating layers on a continuous seed layer, and forming the finger electrodes at the center by providing a continuous plating layer on a continuous seed layer. A detailed description of the embodiment will be given with reference to the drawings. In the explanations of the figures, the same elements shall be denoted by the same reference numerals, and duplicative explanations will be omitted appropriately.

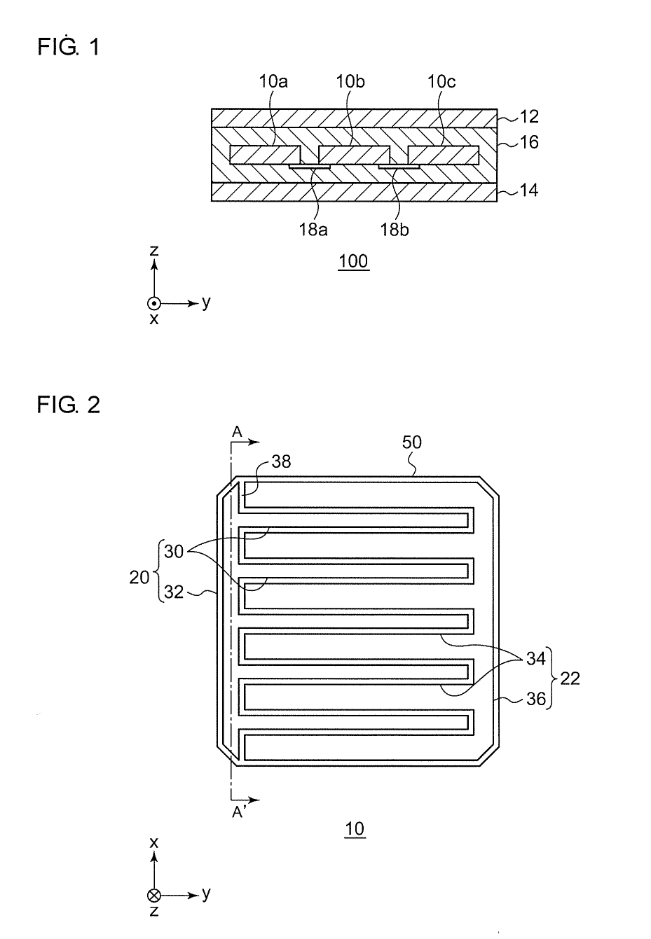

FIG. 1 is a cross sectional view illustrating a structure of a solar cell module 100 according to embodiment 1. The solar cell module 100 includes a first solar cell 10a, a second solar cell 10b, a third solar cell 10c, which are generically referred to as solar cells 10, a first protection member 12, a second protection member 14, an encapsulant 16, a first wiring member 18a, and a second wiring member 18b, which are generically referred to as wiring members 18.

As shown in FIG. 1, a rectangular coordinate system formed by an x axis, y axis, and z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1 and the negative directions are defined in the directions opposite to those of the arrows. Of the two principal, or main surfaces forming the solar cell module 100 that are parallel to the x-y plane, the principal surface provided on the positive direction side along the z axis is the light receiving surface, and the principal surface provided on the negative direction side along the z axis is the back surface. Hereinafter, the positive direction side along the z axis will be referred to as “light receiving surface side” and the negative direction side along the z axis will be referred to as “back surface side”.

The plurality of solar cells 10 form a solar cell string by being arranged along the y axis. The adjacent solar cells 10 are electrically connected by the wiring member 18. The wiring member 18 and the solar cell 10 are bonded by an adhesive. For example, a solder or a resin adhesive agent may be used as an adhesive. The resin adhesive agent may be insulative or contain conductive particles.

The first protection member 12 is provided on the light receiving surface side of the plurality of solar cells 10. The first protection member 12 is formed of, for example, a glass or translucent resin substrate or sheet. Meanwhile, the second protection member 14 is provided on the back surface side of the plurality of solar cells 10. The second protection member 14 is formed of, for example, a resin film.

The encapsulant 16 is provided between the first protection member 12 and the second protection member 14. The encapsulant 16 seals the plurality of solar cells 10. The encapsulant 16 is formed of, for example, a translucent resin such as ethylene-vinyl acetate copolymer (EVA) or polyvinyl butyral (PVB).

A metal (e.g., Al) frame body (not shown) may be mounted to the outer circumference of a stack including the first protection member 12, the encapsulant 16, the solar cells 10, and the second protection member 14. Further, a wiring member and a terminal box for retrieving the output of the solar cells 10 outside may be mounted to the back surface side of the second protection member 14.

FIG. 2 is a plan view illustrating a structure of the solar cell 10 and shows a structure of the back surface of the solar cell 10. The solar cell 10 includes a first electrode 20, a second electrode 22, and a semiconductor substrate 50. The first electrode 20 includes a plurality of finger electrodes 30 for the first electrode and a bus bar electrode 32 for the first electrode, and the second electrode 22 includes a plurality of finger electrodes 34 for the second electrode and a bus bar electrode 36 for the second electrode. The first electrode 20 and the second electrode 22 are formed on the back surface side of the semiconductor substrate 50 and have mutually different conductivity types. To describe it more specifically, the first electrode 20 collects electrons and the second electrode 22 collects holes. The solar cell 10 is a back surface junction type photovoltaic device, and no electrodes are provided on the light receiving surface side.

The plurality of finger electrodes 30 for the first electrode are formed in a rectangular shape extending in the y axis direction. It is assumed here that the number of finger electrodes 30 for the first electrode is “5” but the number is not limited thereto. From the perspective of improving the power generation efficiency of the solar cell 10, it is desired that the number of finger electrodes 30 for the first electrode be large and the width thereof in the x direction be small. The bus bar electrode 32 for the first electrode is connected to the ends of the plurality of finger electrodes 30 for the first electrode on the negative direction side along the y axis. The bus bar electrode 32 for the first electrode is formed in a trapezoidal shape extending in the x axis direction. In the case that the back surface of the solar cell 10 is formed in a rectangular shape, the bus bar electrode 32 for the first electrode may also be formed in a rectangular shape. The first electrode 20 is formed in a comb-tooth shape by the combination of the plurality of finger electrodes 30 for the first electrode and the bus bar electrode 32 for the first electrode. Defining the y axis as the first direction, the x direction can be defined as the second direction perpendicular to the first direction.

The plurality of finger electrodes 34 for the second electrode are formed in a rectangular shape extending in the y axis direction. It is assumed here that the number of finger electrodes 34 for the second electrode is “6” but the number is not limited thereto. From the perspective of improving the power generation efficiency of the solar cell 10, it is desired that the number of finger electrodes 34 for the second electrode be large and the width thereof in the x direction be small. The bus bar electrode 36 for the second electrode is connected to the ends of the plurality of finger electrodes 34 for the second electrode on the positive direction side along the y axis. The bus bar electrode 36 for the second electrode is formed in a trapezoidal shape extending in the x axis direction. The bus bar electrode 36 for the second electrode may be formed in a rectangular shape as in the case of the bus bar electrode 32 for the first electrode. The second electrode 22 is also formed in a comb-tooth shape by the combination of the plurality of finger electrodes 34 for the second electrode and the bus bar electrode 36 for the second electrode.

The first electrode 20 and the second electrode 22 are formed so as to cause the plurality of finger electrodes 30 for the first electrode and the plurality of finger electrodes 34 for the second electrode to be engaged with each other and inserted into each other. An isolation area 38 is provided between the first electrode 20 and the second electrode 22. The isolation area 38 is provided to ensure isolation between the first electrode 20 and the second electrode 22 and is formed to meander along the comb shape of the first electrode 20 and the second electrode 22.

The transparent conductive layer and the metal electrode layer described later that form the first electrode 20 and the second electrode 22 are not provided in the isolation area 38. For this reason, the transparent conductive layer and the metal electrode layer are provided to respectively correspond to the first electrode 20 and the second electrode 22. The area in which the bus bar electrode 32 for the first electrode and the bus bar electrode 36 for the second electrode are formed may be referred to as “first area”, and the area in which the finger electrodes 30 for the first electrode and the finger electrodes 34 for the second electrode are formed may be referred to as “second area”.

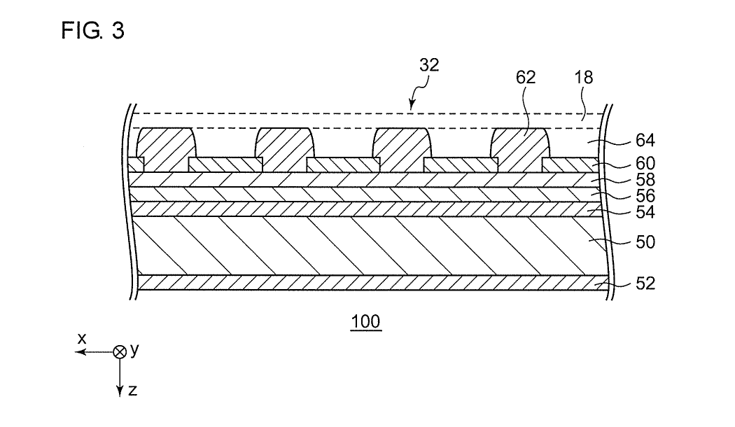

FIG. 3 is an A-A′ cross sectional view illustrating a structure of the solar cell 10. In other words, FIG. 3 is a cross sectional view of a portion of FIG. 2 in which the bus bar electrode 32 for the first electrode is provided. The solar cell 10 includes the semiconductor substrate 50, a protection layer 52, a semiconductor layer 54, a transparent conductive layer 56, a seed layer 58, insulating layers 60, and plating layers 62. The wiring member 18 is bonded to the solar cell 10 by an adhesive 64.

The semiconductor substrate 50 absorbs light incident on the positive direction side along the z axis, i.e., on the light receiving surface side and generates electrodes and holes as carriers. The semiconductor substrate 50 is formed of a crystalline semiconductor wafer having an n-type or p-type conductivity. The semiconductor substrate 50 in the embodiment is assumed to be an n-type monocrystalline silicon wafer.

The protection layer 52 is provided on the positive direction side of the semiconductor substrate 50 along the z axis. The protection layer 52 is formed of, for example, silicon, silicon oxide, silicon nitride, silicon oxynitride, or the like. The protection layer 52 has a function of a passivation layer for the light receiving surface of the semiconductor substrate 50 and a function of an antireflection film and a protection film. The protection layer 52 has a structure in which an i-type amorphous silicon layer, an insulating layer of silicon oxide or silicon nitride, etc. are stacked in sequence on the light receiving surface of the semiconductor substrate 50. The protection layer 52 may have a structure in which an n-type amorphous silicon layer is provided between an i-type amorphous silicon layer and an insulating layer. The i-type amorphous silicon layer and the n-type amorphous silicon layer have a thickness of, for example, about 2 nm-50 nm. The insulating layer of silicon oxide, silicon nitride, or silicon oxynitride or the like has a thickness of, for example, about 50 nm-200 nm.

The semiconductor layer 54 is formed on the negative direction side of the semiconductor substrate 50 along the z axis. The semiconductor layer 54 is formed of an amorphous semiconductor layer having an n-type conductivity like the semiconductor substrate 50. The semiconductor layer 54 is comprised of a dual structure including, for example, a substantially intrinsic i-type amorphous semiconductor layer formed on the back surface of the semiconductor substrate 50 and an n-type amorphous semiconductor layer formed on the i-type amorphous semiconductor layer. In this embodiment, an “amorphous semiconductor” may include a microcrystalline semiconductor. A microcrystalline semiconductor is a semiconductor where semiconductor crystals are precipitated in an amorphous semiconductor.

The -type amorphous semiconductor layer is formed of an i-type amorphous silicon containing hydrogen (H) and has a thickness of, for example, about 2 nm-25 nm. The n-type amorphous semiconductor layer is formed of an n-type amorphous silicon containing hydrogen doped with an n-type dopant and has a thickness of, for example, about 2 nm-50 nm. The method of forming the layers of the semiconductor layer 54 is not particularly limited. For example, the layers may be formed by a chemical vapor deposition (CVD) method such as a plasma CVD method.

The transparent conductive layer 56 is formed on the negative direction side of the semiconductor layer 54 along the z axis. The transparent conductive layer 56 is formed of, for example, a transparent conductive oxide (TCO) such as a tin oxide (SnO₂), a zinc oxide (ZnO), an indium tin oxide (ITO), or the like. The transparent conductive layer 56 according to this embodiment is formed of an indium tin oxide and has a thickness of, for example, about 50 nm-100 nm. The transparent conductive layer 56 can be formed by a thin film formation method such as sputtering and chemical vapor deposition (CVD).

The seed layer 58 is formed on the negative direction side of the transparent conductive layer 56 along the z axis. The seed layer 58 extends in the x axis direction and the y axis direction on the back surface of the semiconductor substrate 50 of FIG. 2. The seed layer 58 forms a metal electrode layer along with the plating layer 62 described later, and the metal electrode layer is formed of a metal material such as copper (Cu), tin (Sn), gold (Au), silver (Ag), nickel (Ni), and titanium (Ti). It is assumed here that the metal electrode layer is formed of copper. The seed layer 58 has a thickness of, for example, about 50 nm 1000 nm. The seed layer 58 is formed by a thin film formation method such as sputtering and chemical vapor deposition (CVD).

The insulating layers 60 are provided discretely in the x axis direction on the negative direction side of the seed layer 58 along the z axis. The insulating layers 60 are discretely arranged at a regular interval. The width of one insulating layer 60 in the x axis direction is equal to or larger than the width between the adjacent insulating layers 60. The insulating layer 60 is formed of, for example, silicon oxide (SiO₂), silicon nitride (SiN), silicon oxynitride (SiON), or the like. The insulating layer 60 is desirably formed of silicon nitride.

The plating layers 62 are formed so as to be connected to the seed layer 58 between the discretely provided insulating layers 60 and project toward the negative direction side along the z axis with respect to the insulating layers 60. Stated otherwise, the plating layers 62 are formed discretely in the x axis direction in the bus bar electrode 32 for the first electrode. The plating layer 62 is formed by plating and has a thickness of about 10 μm 50 μm. In this embodiment, the plating layer 62 is formed on the seed layer 58 that forms the metal electrode layer. Alternatively, the seed layer 58 may not be formed and the plating layer 62 may be formed directly on the transparent conductive layer 56.

The number of plating layers 62 provided in the x axis direction is larger than the number of finger electrodes 30 for the first electrode arranged in the x axis direction. Therefore, the sum of the width of one insulating layer 60 and the width between the adjacent insulating layers 60 in the x axis direction is configured to be smaller than the sum of the width of one finger electrode 30 for the first electrode and the width of the isolation area 38 in the x axis direction. Further, the plating layers 62 are connected to the seed layer 58 of the finger electrodes 30 for the first electrode. A protection plating layer formed of tin or the like may further be provided on the surface of the plating layer 62.

As mentioned above, the plating layers 62 and the seed layer 58 form the metal electrode layer. The dual structure of the metal electrode layer and the transparent conductive layer 56 forms the bus bar electrode 32 for the first electrode. Meanwhile, the finger electrodes 30 for the first electrode are also formed of a stack of the metal electrode layer and the transparent conductive layer 56. However, the plating layers 62 in the bus bar electrode 32 for the first electrode are provided discretely in the x axis direction, but the plating layers 62 in the finger electrodes 30 for the first electrode are provided continuously in the y axis direction. The seed layer 58 in the bus bar electrode 32 for the first electrode is provided continuously in the x axis direction, but the plating layers 62 in the finger electrodes 30 for the first electrode are provided continuously in the y axis direction and are provided discretely in the x axis direction. The insulating layer 60 is not provided and, instead, the plating layers 62 are provided on the negative direction side of the seed layer 58 in the finger electrodes 30 for the first electrode along the z axis direction.

The finger electrodes 30 for the first electrode are provided at the center of the solar cell 10. Therefore, the thickness of the plating layers 62 in the z axis direction is smaller than the thickness thereof in the bus bar electrode 32 for the first electrode provided at the outer circumference of the solar cell module 100. In order to cause the stress in the bus bar electrode 32 for the first electrode to approximate the stress in the finger electrodes 30 for the first electrode, the plating layers 62 are provided discretely in the bus bar electrode 32 for the first electrode and the plating layers 62 are provided continuously in the finger electrodes 30 for the first electrode. Further, the first electrode 20 including the finger electrodes 30 for the first electrode and the bus bar electrode 32 for the first electrode are provided in alignment with the semiconductor layer 54.

Meanwhile, a further semiconductor layer is formed in addition to the semiconductor layer 54 on the negative direction side of the semiconductor substrate 50 along the z axis direction so as to be in alignment with the second electrode 22. The further semiconductor is formed of an amorphous semiconductor layer having a p-type conductivity different from that of the semiconductor substrate 50. The further semiconductor layer is comprised of a dual structure including, for example, a substantially intrinsic i-type amorphous semiconductor layer formed on the back surface of the semiconductor substrate 50 and a p-type amorphous semiconductor layer formed on the i-type amorphous semiconductor layer.

The i-type amorphous semiconductor layer is formed of an i-type amorphous silicon containing hydrogen (H) and has a thickness of, for example, about 2 nm-25 nm. The p-type amorphous semiconductor layer is formed of an n-type amorphous silicon containing hydrogen doped with a p-type dopant and has a thickness of, for example, about 2 nm-50 nm. The method of forming the layers forming the further semiconductor layer is not particularly limited. For example, the layers may be formed by a chemical vapor deposition (CVD) method such as a plasma CVD method.

Further, the finger electrodes 34 for the second electrode are formed in the second electrode 22 similarly as the finger electrodes 30 for the first electrode, and the bus bar electrode 36 for the second electrode is formed similarly as the bus bar electrode 32 for the first electrode.

The adhesive 64 bonds the wiring members 18 and the plating layers 62 in the bus bar electrode 32 for the first electrode. As a result of bonding the wiring member 18 using the adhesive 64, the bus bar electrode 32 for the first electrode is electrically connected to the bus bar electrode 36 for the second electrode in the adjacent solar cell 10 (not shown). Further, another wiring member 18 is bonded by another adhesive 64 to the plating layers 62 in the bus bar electrode 36 for the second electrode (not shown) in the solar cell 10. It is assumed that the adhesive 64 is a resin adhesive.

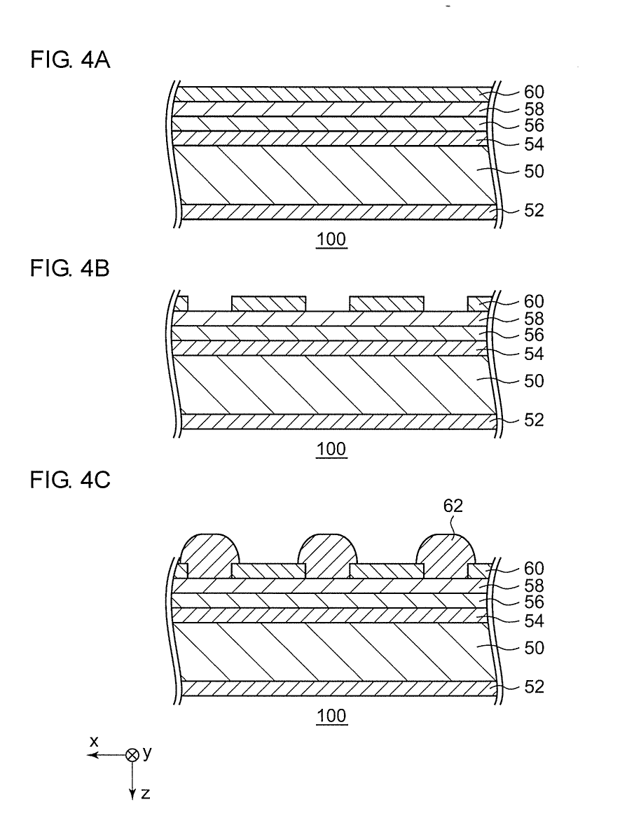

A description will hereinafter be given of a method of manufacturing the solar cell 10 with reference to FIGS. 4A-4C. FIGS. 4A-4C are cross sectional views illustrating steps of manufacturing the solar cell 10, and, in particular, a portion where the bus bar electrode 32 for the first electrode is provided (first area). As shown in FIG. 4A, the protection layer 52 is built on the light receiving surface side of the semiconductor substrate 50. Further, the semiconductor layer 54 is built on the back surface side of the semiconductor substrate 50, and the transparent conductive layer 56 is built on the back surface side of the semiconductor layer 54. Further, the seed layer 58 is built on the back surface side of the transparent conductive layer 56, and the insulating layer 60 is built on the back surface side of the seed layer 58. The method of forming the protection layer 52, the semiconductor layer 54, and the insulating layer 60 is not particularly limited. For example, the layers can be formed by a thin film formation method such as sputtering and chemical vapor deposition (CVD).

Subsequently, as shown in FIG. 4B, the insulating layer 60 is removed discretely along the x axis. It should be noted that the insulating layer 60 is removed at a regular interval. Further, the width removed in the x axis direction is configured to be equal to or smaller than the width of the remaining insulating layer 60 in the x axis direction. The insulating layer 60 is removed by, for example, laser patterning but the method of removing is not limited to this. By removing the insulating layer 60, the seed layer 58 is exposed in selected portions on the back surface side.

Further, as shown in FIG. 4C, the plating layers 62 are formed by plating on the seed layer 58 exposed by discretely removing the insulating layer 60. For example, electroplating may be used. The plating layer 62 is formed by plating on the back surface side of the seed layer 58 in a portion (second area) provided with the finger electrodes 30 for the first electrode. The solar cell 10 shown in FIG. 3 is produced through the above steps.

According to this embodiment, the plating layers are provided discretely in the bus bar electrode so that the volume of the plating layers is reduced. Since the volume of the plating layers is reduced, the stress in the vicinity of the bus bar electrode is reduced. Since the stress in the vicinity of the bus bar electrode is reduced, warp of the solar cell is reduced.

One embodiment of the present invention is summarized below. A solar cell 10 according to an embodiment of the present invention comprises: a semiconductor substrate 50 having a first area and a second area; a seed layer 58 provided on a principal surface of the semiconductor substrate 50 including the first area and the second area; insulating layers 60 discretely provided on the seed layer 58 in the first area and not provided on the seed layer 58 in the second area; and plating layers 62 in the first area connected to the seed layer 58 between the discretely provided insulating layers 60 and connected to the seed layer 58 in the second area.

The solar cell 10 further comprises: a plurality of finger electrodes 30 for a first electrode and a plurality of finger electrodes 34 for a second electrode extending in a first direction on the principal surface of the semiconductor substrate 50 in the second area; and a bus bar electrode 32 for the first electrode and a bus bar electrode 36 for the second electrode connected, on the principal surface of the semiconductor substrate 50 in the first area, to one of ends of the plurality of finger electrodes 30 for the first electrode and the plurality of finger electrodes 34 for the second electrode, respectively, and extending in a second direction perpendicular to the first direction.

Another embodiment of the present invention relates to a method of manufacturing the solar cell 10. The method comprises: building a seed layer 58 on a principal surface of a semiconductor substrate 50 having a first area and a second area and building an insulating layer 60 on the seed layer 58 in the first area; removing the insulating layer 60 in the first area discretely; and forming a plating layer 62 in a portion where the seed layer 58 is exposed as a result of removing the insulating layer 60 in the first area discretely, and forming a plating layer 62 on the seed layer 58 in the second area.

### Embodiment 2

A description will now be given of embodiment 2. Like embodiment 1, embodiment 2 relates to a solar cell of a back surface junction type and is directed to the purpose of reducing in-plane distribution of stress in order to reduce warp of the solar cell. In embodiment 1, the plating layer in the finger electrodes at the center is formed continuously in the longitudinal direction, and the plating layers in the bus bar electrode at the outer circumference are formed discretely in the longitudinal direction. In embodiment 2, the configuration of the plating layers in the bus bar electrode at the outer circumference is different from the configuration described so far. The configuration of the solar cell module 100 according to embodiment 2 is similar to that of FIG. 1, and the configuration of the back surface side of the solar cell 10 is similar to that of FIG. 2. The description here concerns a difference from embodiment 1.

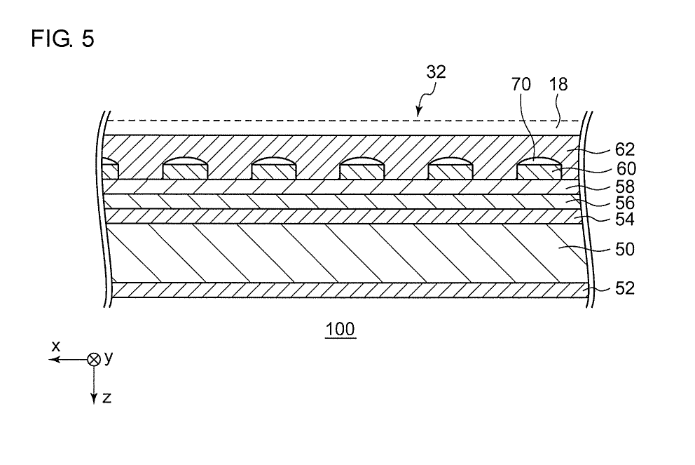

FIG. 5 is an A-A′ cross sectional view illustrating a structure of the solar cell 10 according to embodiment 2. Like FIG. 3, FIG. 5 is a cross sectional view of a portion of FIG. 2 in which the bus bar electrode 32 for the first electrode is provided. In addition to the features of FIG. 3, the solar cell 10 includes cavities 70. The semiconductor substrate 50 through the seed layer 58 in FIG. 5 are similar to those of FIG. 3 so that a description thereof is omitted.

As in FIG. 3, the insulating layers 60 are provided discretely and at a regular interval in the x axis direction on the negative direction side of the seed layer 58 along the z axis. However, the width of one insulating layer 60 in the x axis direction is configured to be smaller than the width of one insulating layer 60 in the x axis direction in FIG. 3. The insulating layer 60 is formed of, for example, silicon nitride.

As in FIG. 3, the plating layers 62 are connected to the seed layer 58 between the discretely provided insulating layers 60. Further, the plating layers 62 project from the portions connected to the seed layer 58 toward the negative direction side along the z axis with respect to the insulating layers 60. Further, the plating layers 62 are connected to each other in the x axis direction at positions spaced apart from the insulating layers 60 in the negative direction in the z axis direction. Therefore, the plating layers 62 are formed to be integrated with each other. As mentioned above, the width of one insulating layer 60 in the x axis direction is smaller than in FIG. 3 so that it is easy to integrate the plating layers 62.

The cavity 70 is formed on the back surface side of each of the insulating layers 60 and is surrounded by the insulating layer 60 and the plating layer 62. The cavity 70 extends in the y axis direction. A plurality of cavities 70 are provided commensurate with the number of insulating layers 60. By providing the cavities 70, the volume of the plating layers 62 is reduced regardless of the integral formation of the plating layers 62. This inhibits the stress in the bus bar electrode 32 for the first electrode from increasing. Meanwhile, the plating layer 62 in the finger electrodes 30 for the first electrode is provided continuously in the y axis direction but does not have the cavities 70. Therefore, the volume of the plating layer 62 is inhibited from being reduced.

The bus bar electrode 36 for the second electrode is formed in the second electrode 22 in a manner similar to the bus bar electrode 32 for the first electrode, and a plurality of cavities 70 are formed in the plating layers 62 of the bus bar electrode 36 for the second electrode.

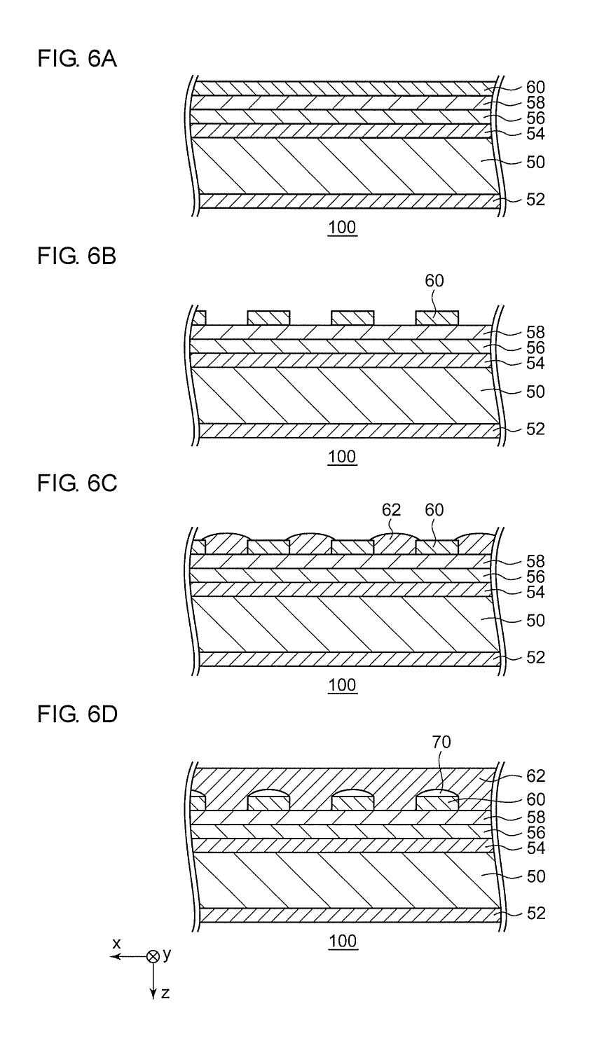

A description will now be given of a method of manufacturing the solar cell 10 with reference to FIGS. 6A-6D. FIGS. 6A-6D are cross sectional views illustrating steps of manufacturing the solar cell 10, and, in particular, a portion where the bus bar electrode 32 for the first electrode is provided. FIGS. 6A-6C are identical to FIGS. 4A-4C so that a description thereof is omitted. FIG. 6D shows a case where electroplating in FIG. 6C is continued. By continuing electroplating from FIG. 6C, the plating layers 62 grow further in the negative direction along the z axis. When the plating layers 62 grow beyond the back surface of the insulating layers 60, they also grow in the x axis direction. After the adjacent plating layers come into contact with each other on the principal surface of the insulating layers, formation of the plating layers is stopped.

The adjacent plating layers 62 come into contact with each other above the insulating layers 60 in the negative direction along the z axis, and the cavities 70 are formed. After the adjacent plating layers 62 come into contact with each other in the x axis direction, formation of the plating layers 62 is stopped.

According to this embodiment, the plating layers are connected to each other at positions spaced apart from the insulating layers so that the volume of the plating layers is reduced, while also forming the plating layers to be integrated with each other. Since the volume of the plating layers is reduced, the stress in the vicinity of the bus bar electrode is reduced. Since the stress in the vicinity of the bus bar electrode is reduced, warp of the solar cell is reduced. Since the plating layers are formed to be integrated with each other, the resistance is inhibited from increasing.

One embodiment of the present invention is summarized below. The plating layers 62 may be formed to be integrated with each other by being connected to each other at positions spaced apart from the insulating layers 60.

The forming of the plating layers 62 may form the plating layers 62 in a direction away from the principal surface of the semiconductor substrate 50 and stop forming the plating layers 62 after the adjacent plating layers 62 come into contact with each other on a principal surface of the insulating layer 60.

### Embodiment 3

A description will now be given of embodiment 3. Like the foregoing embodiments, embodiment 3 relates to a solar cell of a back surface junction type and is directed to the purpose of reducing in-plane distribution of stress in order to reduce warp of the solar cell. In the foregoing embodiments, silicon nitride is used in the insulating layer to reduce the volume of the plating layer in the bus bar electrode. Meanwhile, a resist is used as the insulating layer and the resist is removed ultimately by a solvent or the like. The configuration of the solar cell module 100 according to embodiment 3 is similar to that of FIG. 1, and the configuration of the back surface side of the solar cell 10 is similar to that of FIG. 2. The description here concerns a difference from embodiment 1.

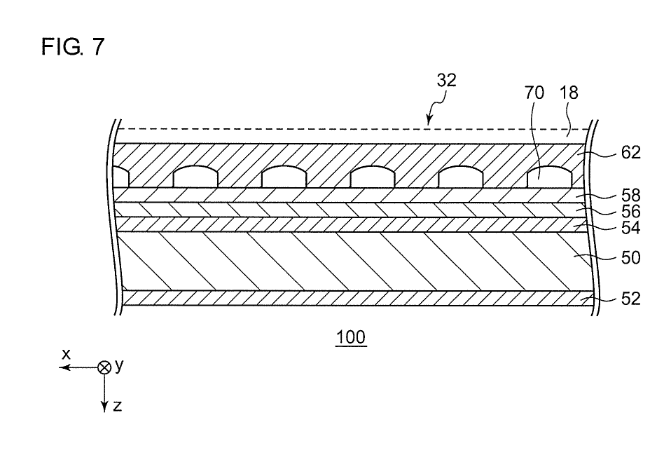

FIG. 7 is an A-A′ cross sectional view illustrating a structure of the solar cell 10 according to embodiment 3. Like FIG. 5, FIG. 7 is a cross sectional view of a portion of FIG. 2 in which the bus bar electrode 32 for the first electrode is provided. In the illustrated solar cell 10, the insulating layers 60 are removed from the configuration of FIG. 5. The semiconductor substrate 50 through the seed layer 58 in FIG. 7 are similar to those of FIG. 5 so that a description thereof is omitted.

The plating layers 62 are formed on the back surface side of the seed layer 58. A plurality of cavities 70 are formed discretely in the x axis direction on the side of the plating layer 62 toward the seed layer 58. Therefore, the plating layers 62 are discretely connected to the seed layer 58 in the x axis direction. The interval between the cavities 70 is configured to be substantially equal to, for example, the interval between the insulating layers 60 in FIG. 5. The plating layer 62 are formed to be integrated with each other also in this embodiment.

The cavities 70 are formed on the back surface side of the seed layer 58 and are surrounded by the seed layer 58 and the plating layers 62. The cavities 70 extend in the y axis direction. A plurality of cavities 70 are provided. As in embodiment 2, by providing the cavities 70, the volume of the plating layers 62 is reduced regardless of the integral formation of the plating layers 62. This inhibits the stress in the bus bar electrode 32 for the first electrode from increasing. Meanwhile, the plating layer 62 in the finger electrodes 30 for the first electrode is provided continuously in the y axis direction but does not have the cavities 70. Therefore, the volume of the plating layer 62 is inhibited from being reduced.

The bus bar electrode 36 for the second electrode is formed in the second electrode 22 in a manner similar to the bus bar electrode 32 for the first electrode, and a plurality of cavities 70 are formed in the plating layers 62 of the bus bar electrode 36 for the second electrode.

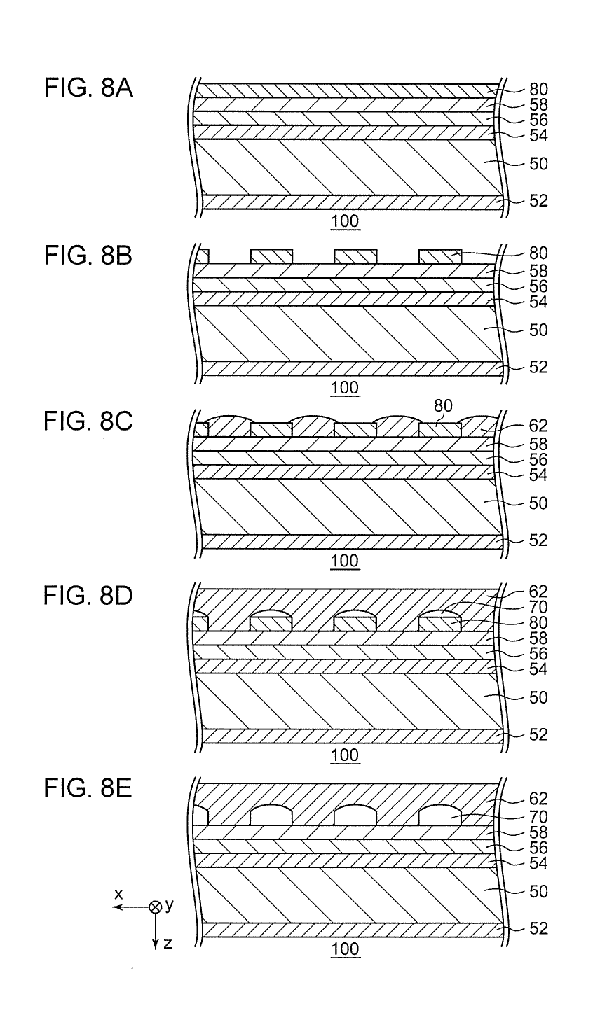

FIGS. 8A-8E are cross sectional views illustrating steps of manufacturing the solar cell 10, and, in particular, a portion where the bus bar electrode 32 for the first electrode is provided. As shown in FIG. 8A, the protection layer 52 is built on the light receiving surface side of the semiconductor substrate 50. Further, the semiconductor layer 54 is built on the back surface side of the semiconductor substrate 50, and the transparent conductive layer 56 is built on the back surface side of the semiconductor layer 54. Further, the seed layer 58 is built on the back surface side of the transparent conductive layer 56, and the insulating layer 80 is built on the back surface side of the seed layer 58. The insulating layer 80 is a resist.

Subsequently, as shown in FIG. 8B, the insulating layer 80 is removed discretely along the x axis. It should be noted that the insulating layer 80 is removed at a regular interval. The insulating layer 80 is removed by, for example, forming a photolithographic pattern. By removing the insulating layer 80, the seed layer 58 is exposed in selected portions on the back surface side. Further, as shown in FIG. 8C, the plating layers 62 are formed by plating on the seed layer 58 exposed by discretely removing the insulating layer 80. For example, electroplating may be used.

Further, as shown in FIG. 8D, electroplating in FIG. 8C is continued. The plating layers 62 grow further in the negative direction along the z axis. When the plating layers 62 grow beyond the back surface of the insulating layer 80, they also grow in the x axis direction. As a result, the plating layers 62 are integrated with each other at positions spaced apart from the insulating layers 80. In the step of integrating the plating layers 62, the cavities 70 are formed between the plating layer 62 and the insulating layers 80. Ultimately, the insulating layer 80 is removed by a solvent or the like. The solar cell 10 shown in FIG. 7 is produced through the above steps.

According to this embodiment, the plating layer is provided with a plurality of cavities so that the volume of the plating layer is reduced. Since the volume of the plating layer is reduced, the stress in the vicinity of the bus bar electrode is reduced. Since the stress in the vicinity of the bus bar electrode is reduced, warp of the solar cell is reduced.

One embodiment of the present invention is summarized below. A solar cell 10 comprises: a semiconductor substrate 50; a plurality of finger electrodes 30 for a first electrode and a plurality of finger electrodes 34 for a second electrode extending in a first direction on a principal surface of the semiconductor substrate 50; and a bus bar electrode 32 for the first electrode and a bus bar electrode 36 for the second electrode connected to one of ends of the plurality of finger electrodes 30 for the first electrode and the plurality of finger electrodes 34 for the second electrode, respectively, and extending in a second direction perpendicular to the first direction. The bus bar electrode 32 for the first electrode and the bus bar electrode 36 for the second electrode are provided with a plurality of cavities 70 extending in the first direction.

The method of manufacturing a solar cell may further comprise removing the insulating layer 60 after integrating the plating layers 62 by bringing the plating layers 62 into contact with each other.

Described above is an explanation based on an exemplary embodiment. The embodiment is intended to be illustrative only and it will be understood by those skilled in the art that various modifications to constituting elements and processes could be developed and that such modifications are also within the scope of the present invention.

In the embodiments, portions where the plating layer is relatively thicker so that warp is likely to occur are configured to be the bus bar electrode 32 for the first electrode and the bus bar electrode 36 for the second electrode. However, based on the reasoning that warp is more likely to occur at the outer circumference of the solar cell than at the center of the solar cell, the plating layer of the finger electrodes 30 for the first electrode closest to the end of the semiconductor substrate 50 will be thicker than that of the finger electrodes 30 for the first electrode provided more toward the center. The same reasoning holds true of the finger electrodes 34 for the second electrode. In this case, a plurality of cavities 70 may be formed in the finger electrodes 30 for the first electrode and in the finger electrode 34 for the second electrode close to the end of the semiconductor substrate 50. The thickness of the plating layer may depend on whether the plating layer is close to the power feeding terminal provided when the plating layer is formed as well as on whether the plating layer is close to the end of the semiconductor substrate 50. Accordingly, warp of the semiconductor substrate 50 is reduced according to the embodiment by providing the cavities 70 discretely in the plating layer in the first area where the plating film is relatively thicker and not providing the cavities 70 in the plating layer in the second area where the plating film is relatively thin.

In embodiments 2 and 3, the plating layers 62 of the finger electrodes 34 for the second electrode are formed continuously in the y axis direction. Alternatively, of the plurality of finger electrodes 34 for the second electrode, the finger electrodes 34 for the second electrode provided at the farthest end in the positive direction in the x axis direction and the finger electrodes 34 provided at the farthest end in the negative direction in the x axis direction may be configured similarly as the bus bar electrode 32 for the first electrode and the bus bar electrode 36 for the second electrode. Stated otherwise, the plating layers 62 in those finger electrodes may be formed with a plurality of cavities 70. This is because those finger electrodes 34 for the second electrode are provided at the outer circumference of the solar cell 10. Since the stress in the vicinity of the bus bar electrode is reduced, warp of the solar cell is reduced.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell comprising:
a semiconductor substrate having a first area and a second area;
a seed layer provided on a principal surface of the semiconductor substrate including the first area and the second area;
insulating layers discretely provided on the seed layer in the first area and not provided on the seed layer in the second area; and
plating layers in the first area connected to the seed layer between the discretely provided insulating layers and connected to the seed layer in the second area.

2. The solar cell according to claim 1, further comprising:
a plurality of finger electrodes extending in a first direction on the principal surface of the semiconductor substrate in the second area; and
a bus bar electrode connected, on the principal surface of the semiconductor substrate in the first area, to one of ends of the plurality of finger electrodes and extending in a second direction perpendicular to the first direction.

3. The solar cell according to claim 2, wherein
the plating layers are formed to be integrated with each other by being connected to each other at positions spaced apart from the insulating layers.

4. A solar cell comprising:
a semiconductor substrate;
a plurality of finger electrodes extending in a first direction on a principal surface of the semiconductor substrate; and
a bus bar electrode connected to one of ends of the plurality of finger electrodes and extending in a second direction perpendicular to the first direction, wherein the bus bar electrode is provided with a plurality of cavities extending in the first direction.

5. A method of manufacturing a solar cell, comprising:
building a seed layer on a principal surface of a semiconductor substrate having a first area and a second area and building an insulating layer on the seed layer in the first area;
removing the insulating layer in the first area discretely; and
forming a plating layer in a portion where the seed layer is exposed as a result of removing the insulating layer in the first area discretely, and forming a plating layer on the seed layer in the second area.

6. The method of manufacturing a solar cell according to claim 5, wherein
the forming of the plating layers forms the plating layers in a direction away from the principal surface of the semiconductor substrate and stop forming the plating layers after the adjacent plating layers come into contact with each other on a principal surface of the insulating layer.

7. The method of manufacturing a solar cell according to claim 6, further comprising:
removing the insulating layer after integrating the plating layers by bringing the plating layers into contact with each other.
